(19) United States
(12) Patent Application Publication
(10) Pub. No.: US 2012/0261731 A1
(43) Pub. Date: Oct. 18, 2012

(54) IMAGE SENSOR

(76) Inventor: Cheng-Hung Yu, Taoyuan County (TW)

(21) Appl. No.: 13/084,558

(22) Filed: Apr. 12, 2011

(51) Int. Cl. H01L 27/146

(52) U.S. Cl. 257/292; 257/E27.134

(57) ABSTRACT

An image sensor is disclosed. The image sensor includes a substrate, at least a color filter, and a microlens disposed on the color filter. The substrate includes a passivation layer thereon, and the color filter is disposed on the passivation layer, in which the color filter is truncated.

### BACKGROUND OF THE INVENTION

1. Field of the Invention

The invention relates to an image sensor, and more particularly, to an image sensor with truncated color filter.

2. Description of the Prior Art

CMOS image sensors (CISs) and charge-coupled devices (CCDs) are optical circuit components that represent light signals as digital signals. CISs and CCDs are used in the prior art. These two components widely applied to many devices, including: scanners, video cameras, and digital still cameras. CCDs use is limited in the market due to price and the volume considerations. As a result, CISs enjoy greater popularity in the market.

The CIS is manufactured utilizing the prior art semiconductor manufacturing process. This process helps to decrease the cost and the component size. It is applied in digital products such as personal computer cameras such as Web cams and digital cameras. Currently, the CIS can be classified into two types: line type and plane type. The line type CIS is applied in scanners, and the plane type CIS is applied in digital cameras.

However, as the image sensors progress toward the direction of smaller pitch, small size, and 3D compact device, the chief-ray angle of the image sensors also increases accordingly, which further worsens problem such as vignetting. Hence how to effectively direct light from microlenses into image sensor has become an important task in this field.

### SUMMARY OF THE INVENTION

It is an objective of the present invention to provide an image sensor for solving the issue met by conventional image sensor.

According to a preferred embodiment of the present invention, an image sensor is disclosed. The image sensor includes a substrate, at least a color filter, and a microlens disposed on the color filter. The substrate includes a passivation layer thereon, and the color filter is disposed on the passivation layer, in which the color filter is truncated.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7, FIGS. 1-7 are schematic, cross-sectional diagrams illustrating a method for fabricating an image sensor in accordance with a first preferred embodiment of the present invention.

FIG. 8 illustrates a perspective view of an image sensor according to another embodiment of the present invention.

FIG. 9 illustrates a perspective view of increasing the area for receiving light through truncated color filter and inner lens of the present invention.

FIG. 10 illustrates a structural view of a BSI CMOS image sensor according to an embodiment of the present invention.

### DETAILED DESCRIPTION

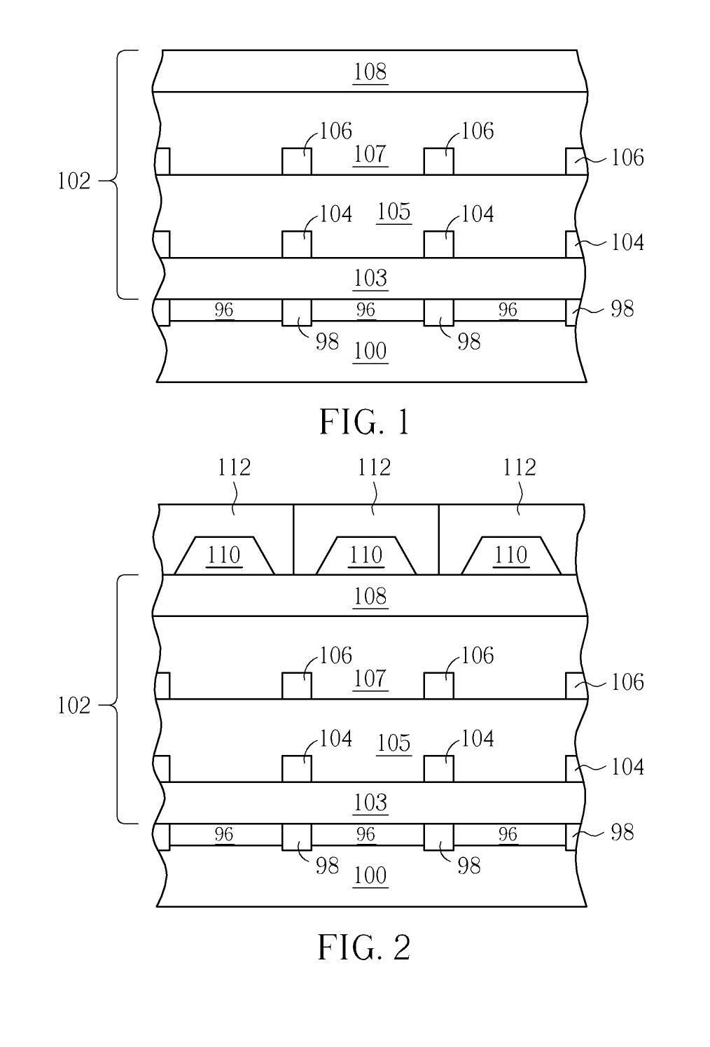

Referring to FIGS. 1-6, FIGS. 1-6 are schematic, cross-sectional diagrams illustrating a method for fabricating an image sensor in accordance with the first preferred embodiment of the present invention. As shown in FIG. 1, the present invention first provides a substrate 100 with a dielectric layer 102 thereon. The substrate 100 is a semiconductor substrate, but is not limited to a silicon wafer or a SOI, and the substrate 100 may include a plurality of light sensitization devices 96 such as photodiodes, etc., to receive the outside light beams and sensor the light intensity, and a plurality of insulators 98 such as shallow trench isolations (STIs), or local oxidation of silicon isolation layers (LOCOSs), etc., to avoid shorts and contact of the light sensitization devices 96 with MOS transistors and other devices. The light sensitization devices 96 are further electrically connected to CMOS transistors (not shown) such as reset transistors, current source followers, or row selectors. Furthermore, the dielectric layer 102 may include an inter layer dielectric (ILD) layer 103, an inter metal dielectric (IMD) layer 105, a planarized layer 107, and a passivation layer 108 such as silicon nitride, etc. A plurality of metal layers 104 and metal layers 106 of multilevel interconnects layer are formed between the IMD layer 105 and the planarized layer 107 as circuit connections of the light sensitization devices 96, MOS transistors, and other devices. The metal layers 104 and the metal layers 106 are formed above every STI and CMOS transistors for preventing each light sensitization devices 96 from covering. The incident light (not shown) is gathered into the light sensitization devices 96 without cross talk caused from the scattering.

Next, as shown in FIG. 2, a dielectric material (not shown) is formed on the passivation layer 108, and a pattern transfer process, such as one or more than one etching process is conducted to partially remove the dielectric material for forming a plurality of truncated inner lenses 110 on the passivation layer 108. In this embodiment, the inner lenses 110 are preferably composed of silicon dioxide or silicon nitride, and the material used for the inter lenses 110 and the passivation layer 108 could be the same or different.

Next, a plurality of color filter layers (not shown) is formed on the passivation layer 108 accompanying a plurality of exposure and development processes to form a plurality of color filters 112 on the passivation layer 108 and the inner lenses 110, in which each of the color filters 112 corresponds to each photodiode in the substrate 100. The color filters 112 could include red color filter, green color filter, blue color filter, or color filters of other colors. It should be noted that the inner lenses 110 of this embodiment is a selective structure. Hence, depending on the demand of the product, the process for fabricating the aforementioned inner lenses 110 could be omitted and the color filters 112 could be formed directly on the passivation layer 108 without forming any inner lens 110 therebetween, which is within the scope of the present invention.

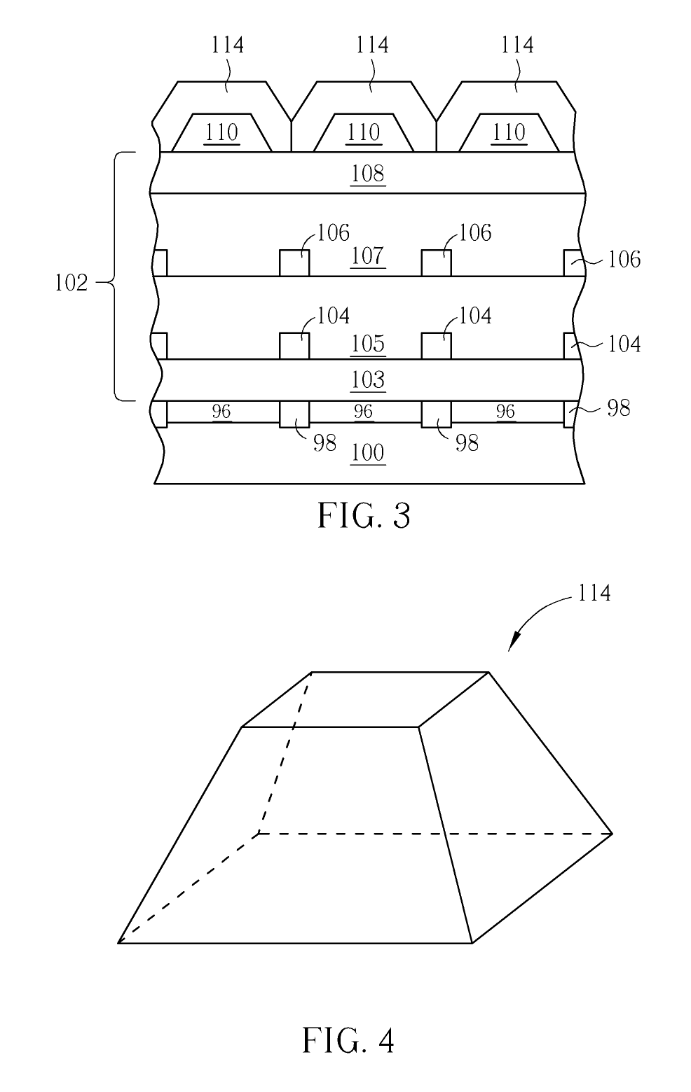

Next, as shown in FIG. 3, a patterned planar layer (not shown) could be formed on the surface of the color filters 112, and an exposure and development process is performed by using the patterned planar layer as mask to remove a portion of the edge of each color filter 112 for forming four slanted surfaces. This creates a plurality of truncated color filters 114 and the patterned planar layer is then removed. Referring to FIG. 4, which illustrates a 3D view of the color filter 114 is truncated square pyramid. Cone, tetrahedron, pentagonal pyramid, or polygonal pyramid with truncations are also possible. It should be noted that instead of using the aforementioned exposure and development process to fabricate the truncated color filters 114, an etching process could also be performed by using etching gas such as oxygen to partially remove the edge of each color filter 112 for forming the truncated color filters 114, which is also within the scope of the present invention.

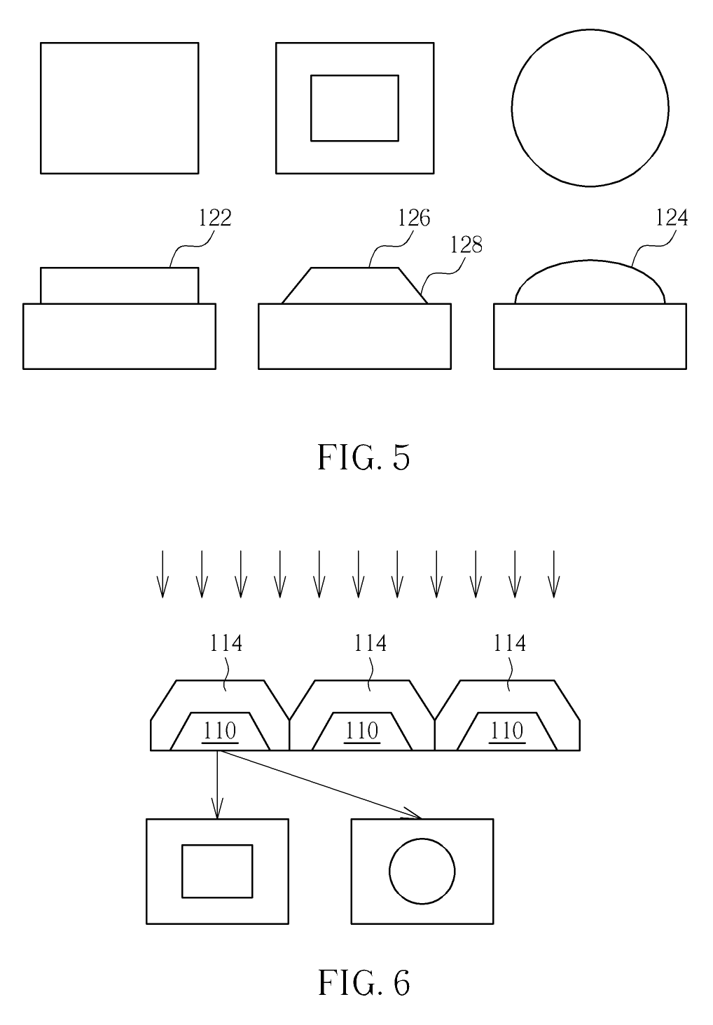

Next, referring to FIG. 5, which illustrates a comparative diagram between light-receiving area of the color filter of the present invention and the prior art. As shown in the figure, the conventional color filter is either rectangular as shown on the left side of the figure, or circular as shown on the right side of the figure. In contrast to the conventional design of only employing a planar top surface 122 or a circular top surface 124 for accepting light, the truncated color filter of the present invention specifically employs a top surface and four side surfaces for accepting light. If the area capable of receiving light were calculated by using a side of 2.2 μm for the rectangle or a diameter of 2.2 μm for the circle, the entire area of accepting light under same thickness for the conventional rectangular color filter is 4.84 μm² and the area of receiving light for the conventional circular color filter is approximately 7.60 μm². The area of the color filter for receiving light of the present invention, which preferably includes the total area of the top surface 126 and the area of the four surrounding inclined surfaces 128, is substantially equal to 8.815 μm². Hence, the pyramidal color filter having truncations of the present invention preferably has an increase of 82% in light receiving area compare with conventional rectangular color filter and an increase of 16% compare with conventional circular color filter.

It should be noted that the planar layer used to transfer pattern for the color filter 112 is not limited to any shape. Referring to FIG. 6, which illustrates a perspective view of using different shape of patterned planar layer as mask for forming the color filter. As shown in the figure, if a rectangular patterned planar layer is used to perform a pattern transfer for the color filter 112, the top surface of the color filters 114 formed would become rectangular, whereas if a circular patterned planar layer is used to perform a pattern transfer for the color filter 112, the top surface of the color filters 114 formed would become circular.

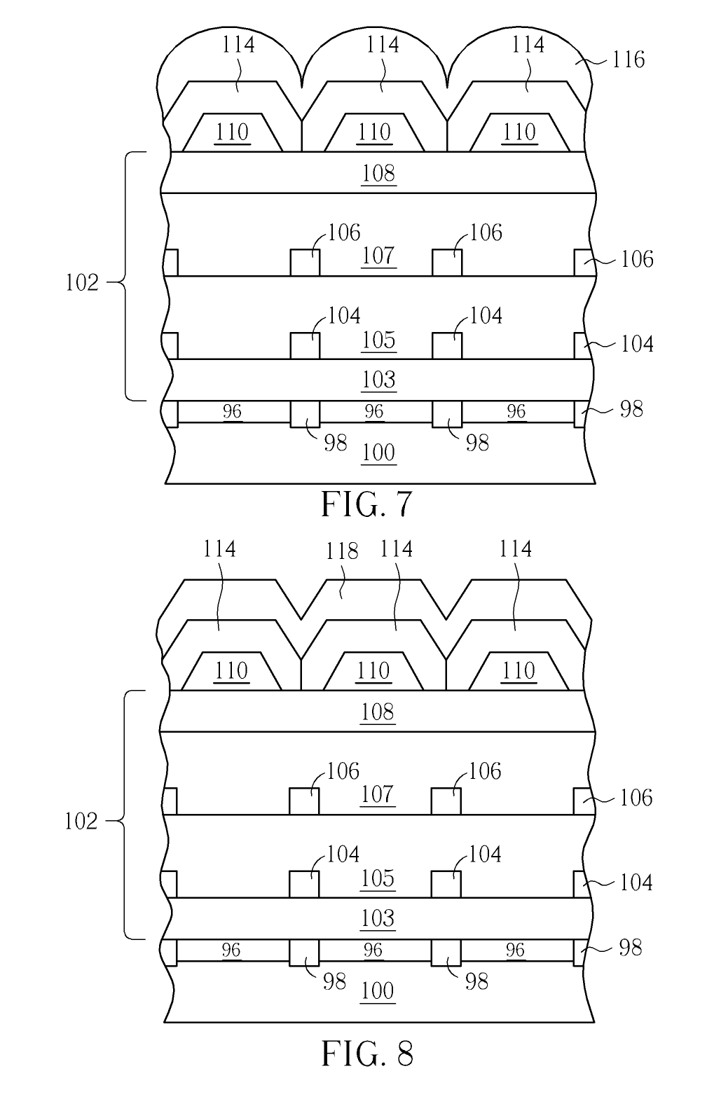

Next, as shown in FIG. 7, a polymer layer (not shown) composed of acrylate material is covered on the color filters 114 after the truncations of the color filters 114 are formed. An exposure and development process is then conducted on the polymer layer, and a baking process is accompanied to transform the polymer layer into a plurality of semi-circular microlenses 116 on the color filters 114. This completes the fabrication of an image sensor according to a first embodiment of the present invention. It should be noted that even though the microlenses 116 are formed directly on the truncated color filters 114, an additional planar layer (not shown) could be selectively formed on the color filters 114 before the microlenses 116 are fabricated, which is also within the scope of the present invention.

Next, referring to FIG. 8, which illustrates a perspective view of an image sensor according to another embodiment of the present invention. As shown in the figure, after the truncated color filters 114 are formed from FIG. 3, a photosensitive material without requiring any baking process could be covered on the color filters 114 according to the demand of the process, and an exposure and development process is carried out on the photosensitive material. By adjusting the location and intensity of the exposure used in the process, the photosensitive material is transformed into the truncated microlenses 118 shown in FIG. 7.

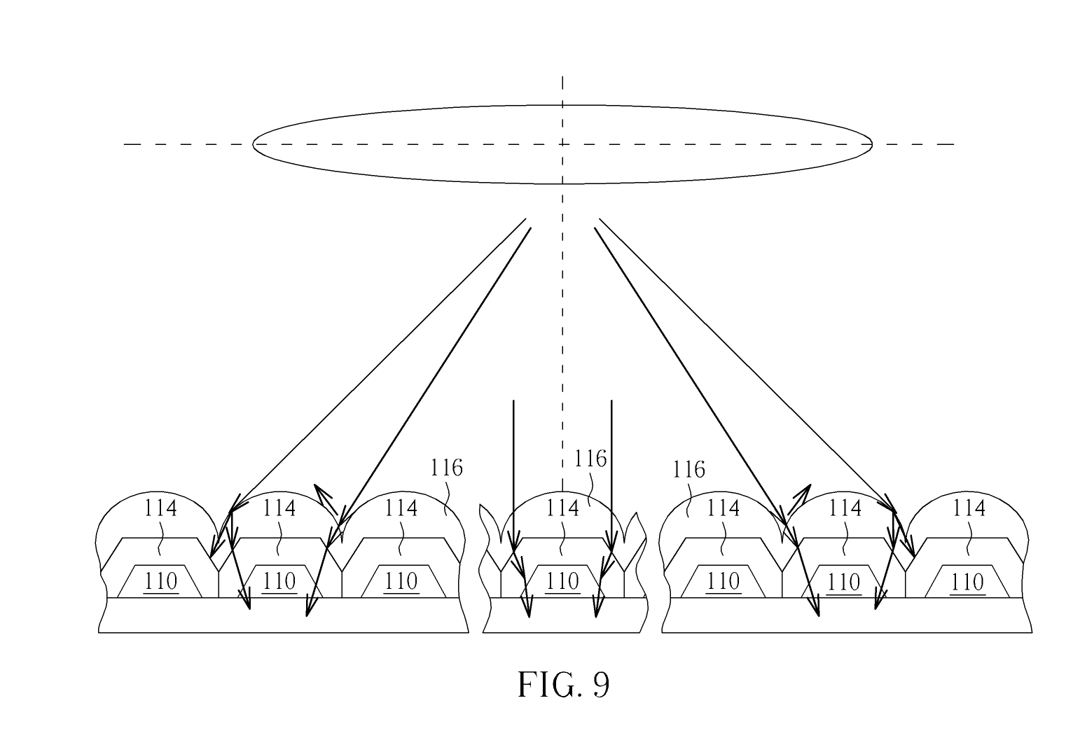

As shown in FIG. 9, the present invention could effectively use the truncated surface of the color filter 114 and the inner lens 110 to increase the area for receiving light into the image sensor, such that by using the rough surface of the color filter and inner lens to reduce reflection of light, external lights could be gathered to enter the image sensor much more easily. This design not only increases the chief-ray angle of the device, but also improves the problem of vignetting and brightness uniformity with respect to the edge of the image.

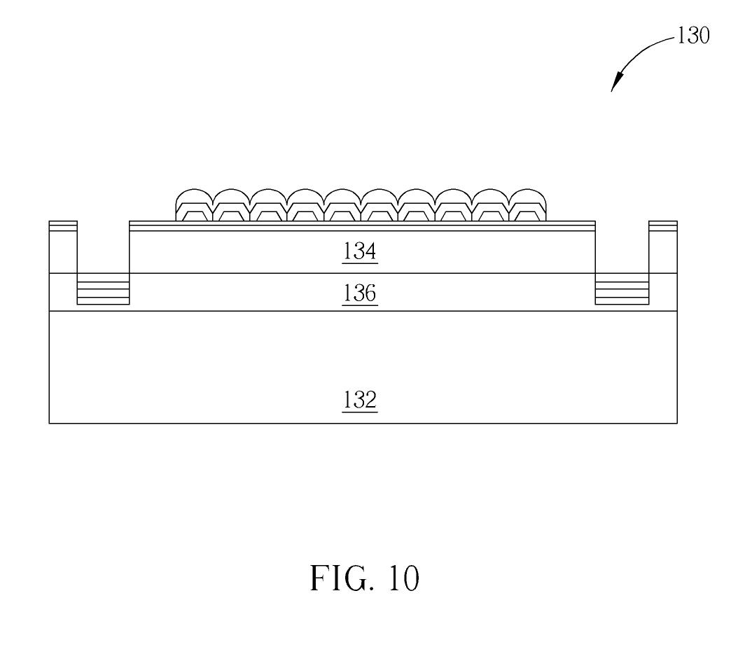

Moreover, as shown in FIG. 10, the truncated inner lens, color filter, and/or microlens of the present invention could also be applied to a back-side illuminated (BSI) CMOS image sensor 130. As shown in the figure, the BSI CMOS image sensor 130 includes a carrier substrate 132, a silicon substrate 134, and a metal interconnect layer 136 disposed between the carrier substrate 132 and the silicon substrate 134. The truncated inner lens, color filter, and/or microlens of the present invention could be formed on the surface of the silicon substrate 134 opposite to the surface the metal interconnect layer 136 disposed on. By following this design, the present invention could not only maintain the advantage of having better sensitivity and coloring of a typical BSI CMOS image sensor, but also use the truncated surface design to improve the overall performance of the image sensor.

Overall, the present invention preferably performs a pattern transfer process during a color filter fabrication, such as using an exposure and development process or an etching process to partially remove the color filter for forming color filters with at least one truncation. By forming truncations in the color filter, the present invention could increase the surface area for absorbing outside light beams such that more light could be attracted into the photodiode through the color filters thereby improving problem such as vignetting. Moreover, the design of the truncations could be further employed in a similar manner to the inner lenses above the passivation layer as well as the microlenses disposed on top of the color filters for forming inner lenses and microlenses with truncations.

Those skilled in the art will readily observe that numerous modifications and alterations of the device and method may be made while retaining the teachings of the invention.

What is claimed is:

1. An image sensor, comprising:
a substrate, wherein the substrate comprises a passivation layer thereon;
at least a color filter disposed on the passivation layer, wherein the color filter is truncated; and
a microlens, disposed on the color filter.

2. The image sensor of claim 1, wherein the substrate comprises at least a light sensitization device.

3. The image sensor of claim 1, wherein the microlens is truncated.

4. The image sensor of claim 1, further comprising at least an inner lens disposed on the passivation layer, wherein the color filter covers the inner lens.

5. The image sensor of claim 4, wherein the inner lens is truncated.

6. The image sensor of claim 4, wherein the inner lens and the passivation layer comprise same material.

7. The image sensor of claim 4, wherein the inner lens comprises silicon dioxide or silicon nitride.

8. The image sensor of claim 1, wherein the image sensor comprises a CMOS image sensor, and the substrate comprises at least a photodiode corresponding to the microlens.

9. An image sensor, comprising:
a substrate, wherein the substrate comprises a passivation layer thereon;
an inner lens disposed on the passivation layer, wherein the inner lens is truncated;
at least a color filter disposed on the inner lens; and
a microlens, disposed on the color filter.

10. The image sensor of claim 9, wherein the substrate comprises at least a light sensitization device.

11. The image sensor of claim 9, wherein the microlens is truncated.

12. The image sensor of claim 9, further comprising at least an inner lens disposed on the passivation layer, wherein the color filter covers the inner lens.

13. The image sensor of claim 9, wherein the inner lens and the passivation layer comprise same material.

14. The image sensor of claim 9, wherein the inner lens comprises silicon dioxide or silicon nitride.

15. The image sensor of claim 9, wherein the image sensor comprises a CMOS image sensor, and the substrate comprises at least a photodiode corresponding to the microlens.
